(19) United States
(12) Patent Application Publication
(10) Pub. No.: US 2017/0244361 A1
(43) Pub. Date: Aug. 24, 2017

(54) WIDE-BAND VOLTAGE-CONTROLLED OSCILLATOR (VCO) WITH SWITCHED INDUCTOR CIRCUIT

(71) Applicant: QUALCOMM Incorporated, San Diego, CA (US)

(72) Inventors: Mohammad FARAZIAN, San Diego, CA (US); Masoud MOSLEHI BAJESTAN, San Diego, CA (US)

(21) Appl. No.: 15/048,460

(22) Filed: Feb. 19, 2016

(51) Int. Cl. H03B 5/12

(52) U.S. Cl. CPC H03B 5/1228; H03B 5/1268; H03B 5/1265; H03B 5/1212

(57) ABSTRACT

Certain aspects of the present disclosure generally relate to a voltage-controlled oscillator (VCO) that is configurable (e.g., in a dynamic manner) in multiple modes of operation (e.g., low/high-band modes). The VCO may include a resonant circuit coupled to a plurality of switches that may be used to adjust current flow within one or more inductive elements of the resonant circuit. By adjusting the current flow within the inductive elements, an inductance of the resonant circuit may be adjusted, which in turn adjusts a band of the VCO.

### TECHNICAL FIELD

Certain aspects of the present disclosure generally relate to radio frequency (RF) circuits and, more particularly, to voltage-controlled oscillators (VCOs).

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology), 4G, 5G, or later system, which may provide network service via any one of various radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System-Time Division Duplexing), HSPA (High Speed Packet Access), GPRS (General Packet Radio Service), or EDGE (Enhanced Data rates for Global Evolution). Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3^{rd} Generation Partnership Project (3GPP) Long Term Evolution (LTE) networks, and Long Term Evolution Advanced (LTE-A) networks. Other examples of wireless communication networks may include WiFi (in accordance with IEEE 802.11), WiMAX (in accordance with IEEE 802.16), and Bluetooth® networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

In order to transmit or receive data and/or control information, the radio frequency front end of the base station and/or the mobile station may include one or more frequency synthesizers to generate oscillating signals used for upconverting baseband signals and downconverting radio frequency (RF) signals. At least one of the frequency synthesizers may include a voltage-controlled oscillator (VCO) for tuning an oscillating signal to different frequencies. In modern communication systems, it is typically desirable to use VCOs with a wide tuning range, low phase noise, low power consumption, and low area occupation.

### SUMMARY

Certain aspects of the present disclosure generally relate to a voltage-controlled oscillator (VCO) that is configurable (e.g., in a dynamic manner) in multiple modes of operation (e.g., low/high-band modes).

Certain aspects of the present disclosure provide a VCO. The VCO generally includes a resonant circuit configured to generate at least one oscillating signal and having a first port, a second port, a third port, and a fourth port, the resonant circuit comprising a first inductive element connected between the first port and the third port and having a first node, a second inductive element connected between the second port and the fourth port and having a second node, a first inductive loop connected between the first node and the second node, and a second inductive loop connected between the first node and the second node; and a plurality of switches configured to selectively connect each of the first port and the second port with respective ones of the third port and the fourth port.

Certain aspects of the present disclosure provide a method for generating at least one oscillating signal. The method generally includes determining a mode of operation of an apparatus having at least one resonant circuit, the resonant circuit comprising first and second inductive elements and first and second inductive loops, each of the first and second inductive loops being connected between a node of the first inductive element and a node of the second inductive element; selectively connecting a first port connected to the first inductive element with either a third port connected to the first inductive element or a fourth port connected to the second inductive element, based on the determination; selectively connecting a second port connected to the second inductive element with the other port of the third port and the fourth port; and generating the at least one oscillating signal based on the selective connection of the first and second ports with the third and fourth ports.

Certain aspects of the present disclosure provide an apparatus for generating at least one oscillating signal. The apparatus generally includes means for determining a mode of operation of the apparatus having a resonant circuit, the resonant circuit comprising first and second inductive elements and first and second inductive loops, each of the first and second inductive loops being connected between a node of the first inductive element and a node of the second inductive element; means for selectively connecting a first port connected to the first inductive element with either a third port connected to the first inductive element or a fourth port connected to the second inductive element, based on the determination; means for selectively connecting a second port connected to the second inductive element with the other port of the third port and the fourth port; and means for generating the at least one oscillating signal based on the selective connection of the first and second ports with the third and fourth ports.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network in accordance with certain aspects of the present disclosure.

FIG. 2 is a block diagram of an example access point (AP) and example user terminals in accordance with certain aspects of the present disclosure.

FIG. 3 is a block diagram of an example transceiver front end in accordance with certain aspects of the present disclosure.

FIG. 4 illustrates an example VCO having a switched inductor circuit, in accordance with certain aspects of the present disclosure.

FIG. 5A illustrates an example layout of the switched inductor circuit of FIG. 4, in accordance with certain aspects of the present disclosure.

FIG. 5B illustrates mode selection switches of FIG. 5A, in accordance with certain aspects of the present disclosure.

FIG. 6A illustrates example current flow through the layout of the switched inductor circuit of FIG. 5A during a low-band mode of operation, in accordance with certain aspects of the present disclosure.

FIG. 6B is an equivalent circuit diagram for the switched inductor circuit of FIG. 6A during the low-band mode of operation, in accordance with certain aspects of the present disclosure.

FIG. 7A illustrates example current flow through the layout of the switched inductor circuit of FIG. 5A during a high-band mode of operation, in accordance with certain aspects of the present disclosure.

FIG. 7B is an equivalent circuit diagram for the switched inductor circuit of FIG. 7A during the high-band mode of operation, in accordance with certain aspects of the present disclosure.

FIG. 8 is a three-dimensional (3D) illustration of an example layout of a switched inductor circuit, in accordance with certain aspects of the present disclosure.

FIG. 9 illustrates another example layout of the switched inductor circuit of FIG. 4, in accordance with certain aspects of the present disclosure.

FIGS. 10A and 10B are equivalent circuit diagrams for the switched inductor circuit of FIG. 9 during the low-band and high-band modes of operation, respectively, in accordance with certain aspects of the present disclosure.

FIG. 11 illustrates example operations for generating at least one oscillating signal, in accordance with certain aspects of the present disclosure.

### DETAILED DESCRIPTION

Certain aspects of the present disclosure generally relate to a voltage-controlled oscillator (VCO) that is configurable (e.g., in a dynamic manner) in multiple modes of operation (e.g., low/high-band modes). The VCO may include a resonant circuit coupled to a plurality of switches that may be used to adjust current flow within one or more inductive elements of the resonant circuit. By adjusting the current flow within the inductive elements, an inductance of the resonant circuit may be adjusted, which in turn adjusts the operating band of the VCO. The VCO may be used to generate a local oscillator (LO) signal in a wireless device (e.g., access point or user terminal) of a wireless system, described in more detail herein.

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards. A TDMA system may implement Global System for Mobile Communications (GSM) or some other standards. These various standards are known in the art.

### An Example Wireless System

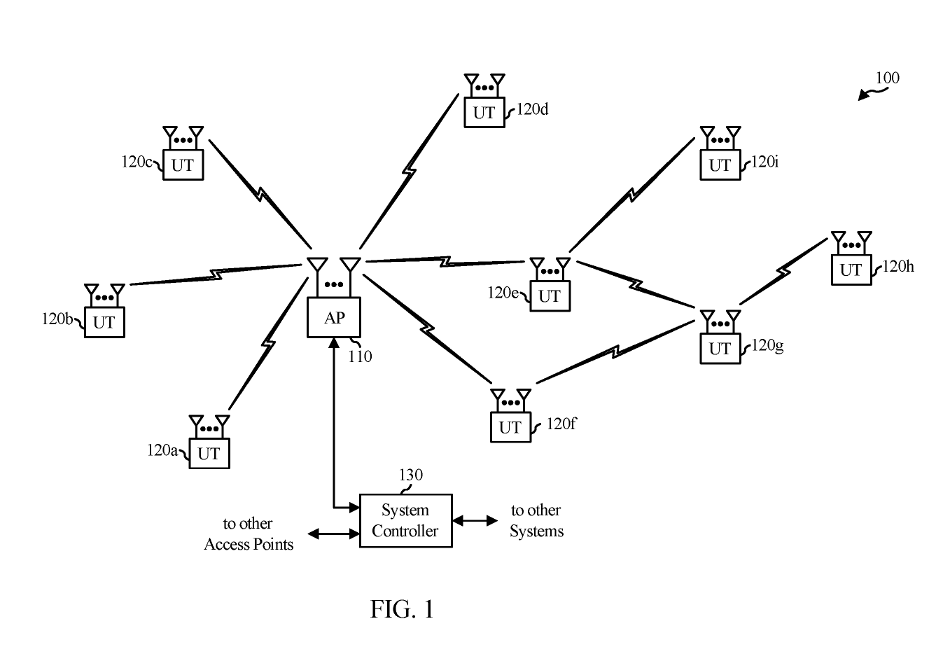

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≧1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., in order to keep costs down) or multiple antennas (e.g., where the additional cost can be supported).

In certain aspects of the present disclosure, the access point 110 or user terminals 120 may include a VCO having a resonant circuit, wherein an inductance of the resonant circuit is implemented using a switched inductor circuit. Current flow within the switched inductor circuit may be adjusted via one or more switches to adjust an operating band of the VCO.

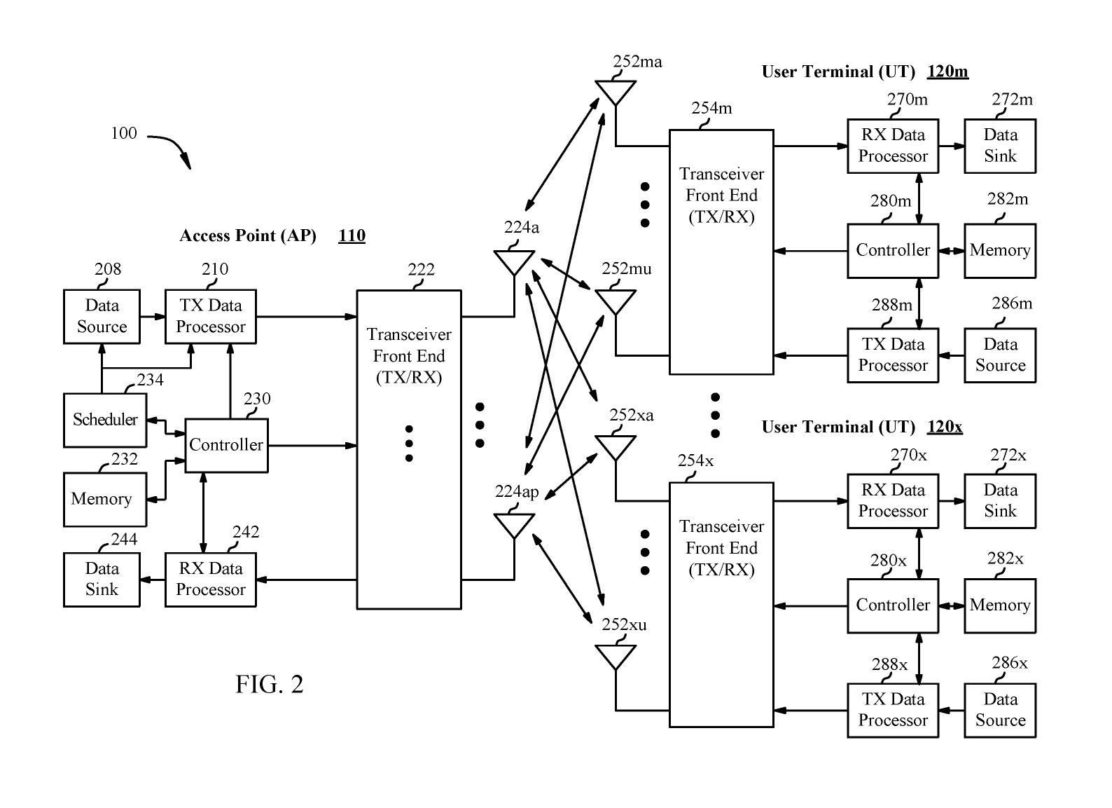

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol stream for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof.

In certain aspects of the present disclosure, transceiver front end 222 or transceiver front end 254 may include a VCO having a resonant circuit, wherein an inductance of the resonant circuit is implemented using a switched inductor circuit. Current flow within the switched inductor circuit may be adjusted (e.g., by controller 230 and/or 280) via one or more switches to adjust an operating band of the VCO.

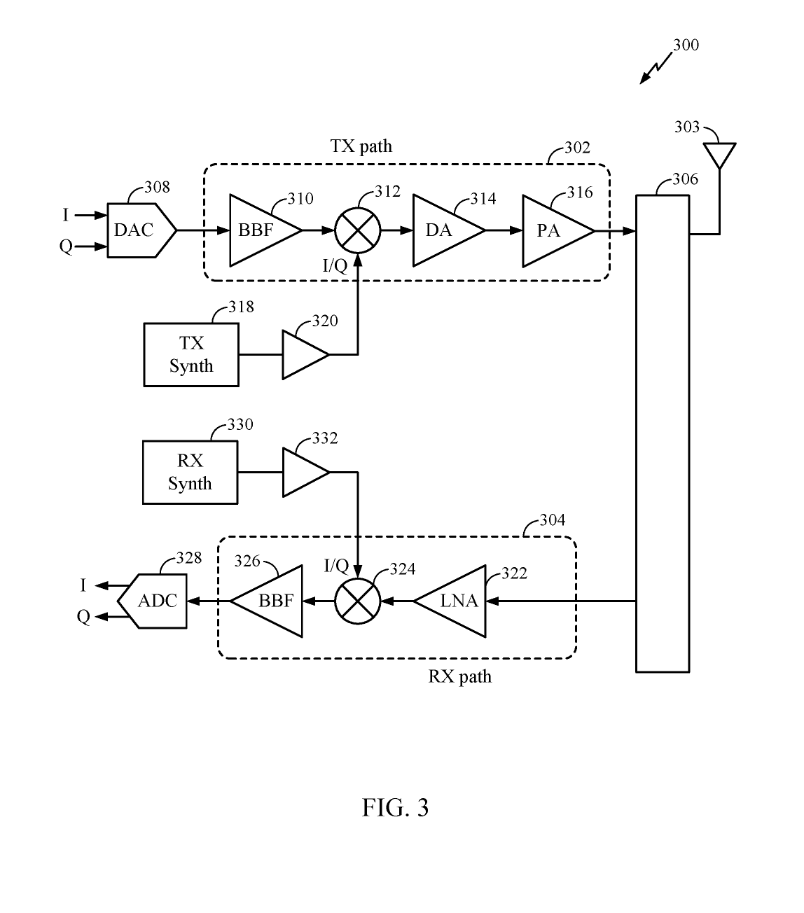

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). Known as heterodyning, this frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 may include a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO may be produced by a TX frequency synthesizer 318, which may be buffered or amplified by amplifier 320 before being mixed with the baseband signals in the mixer 312. Similarly, the receive LO may be produced by an RX frequency synthesizer 330, which may be buffered or amplified by amplifier 332 before being mixed with the RF signals in the mixer 324.

In certain aspects of the present disclosure, the VCO of TX frequency synthesizer 318 or RX frequency synthesizer 330 may include a resonant circuit, wherein an inductance of the resonant circuit is implemented using a switched inductor circuit. Current flow within the switched inductor circuit may be adjusted via one or more switches to adjust an operating band of the VCO.

### Example VCO with Switched Inductance

Wireless communication devices (e.g., access point 110 or user terminals 120) may operate across a wide range of frequency bands. For example, signals may be received by a wireless device at frequencies that are within different bands. As a result, multiple VCOs may be used to cover a wide frequency range within which various signals may be received by a device. However, using multiple VCOs may come at the cost of increased power and area consumption and a degradation in phase noise. In other solutions for achieving a wide range, the quality factor (Q) of the resonant circuit may suffer for at least one mode of oscillation (e.g., a high band Q<10).

Aspects of the present disclosure provide a switched inductor VCO that can cover a wide frequency range (e.g., more than one octave). The switched inductor VCO of the present disclosure may be configurable for operation in different modes corresponding to different bands, such as low, medium, high, and ultra-high bands (which may all be 3GPP bands). Furthermore, the area occupation of the switch inductor VCO may be relatively low, and the Q for higher resonant frequencies may be relatively large, compared to other VCO solutions for achieving wide frequency range.

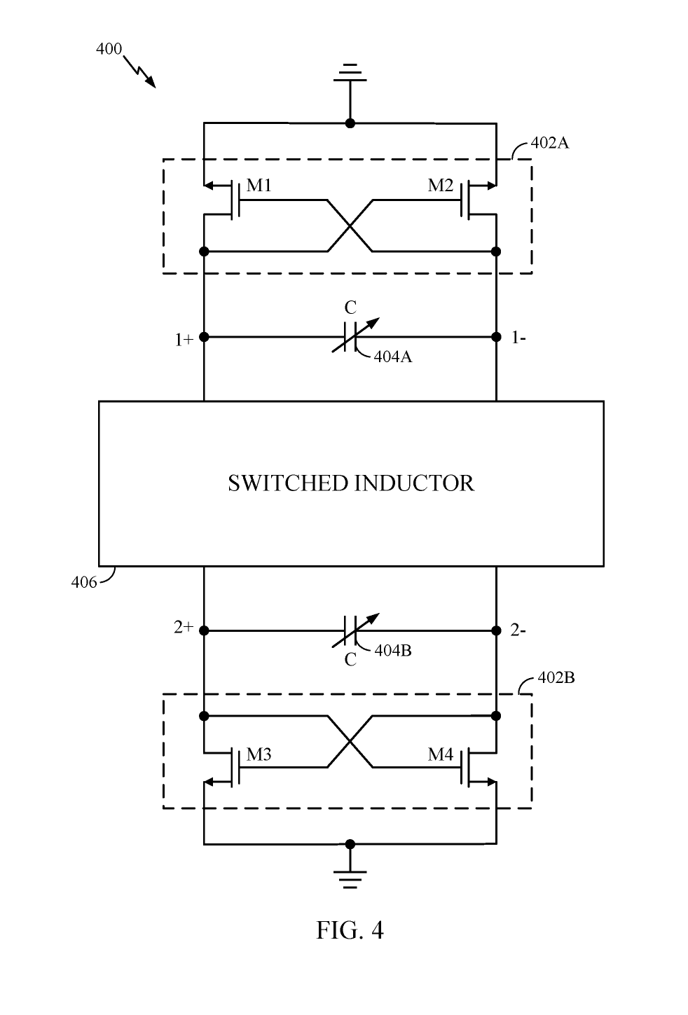

FIG. 4 illustrates an example VCO 400 having a switched inductor circuit, in accordance with certain aspects of the present disclosure. As illustrated, the VCO 400 includes a negative transconductance (−Gm) circuit 402A and another negative transconductance circuit 402B (collectively “negative transconductance circuits 402”). In certain aspects, each of the negative transconductance circuits 402 may be implemented with cross-coupled n-channel metal oxide semiconductor (NMOS) transistors or cross-coupled p-channel metal oxide semiconductor (PMOS) transistors. In certain aspects, the negative transconductance circuits 402 may be implemented using a pair of NMOS and PMOS cross-coupled transistors, for a complementary metal oxide semiconductor (CMOS) implementation. For example, negative transconductance circuit 402A may be implemented with cross-coupled NMOS transistors M1 and M2, and negative transconductance circuit 402B may be implemented with cross-coupled NMOS transistors M3 and M4, as depicted.

The negative transconductance circuits 402 may be coupled to a resonant circuit (also referred to as an inductor-capacitor (LC) circuit, a tank circuit, or a tuned circuit) for generating an oscillating signal. The resonant circuit of the VCO 400 may include variable capacitive elements 404A and 404B (collectively “variable capacitive elements 404”) connected with a switched inductor circuit 406. Each of the variable capacitive elements 404 may be implemented with one or more varactors (e.g., variable capacitors) and/or one or more banks of switchable capacitors. The negative transconductance circuit 402A may be coupled to a positive voltage terminal (labeled “1+”) and a negative voltage terminal (labeled “1−”) of the resonant circuit. The negative transconductance circuit 402B may be coupled to a positive voltage terminal (labeled “2+”) and a negative voltage terminal (labeled “2−”) of the resonant circuit. Power for the VCO 400 may be supplied from a voltage supply rail, which may have a more positive voltage than a reference potential (e.g., electrical ground) for the VCO. The voltage supply rail may be connected with a center tap (not shown) of an inductor in the switched inductor circuit 406.

The inductance of the switched inductor circuit 406 may be configured by controlling switches within the switched inductor circuit. For example, a controller (e.g., controller 230 or 280) or any other suitable processor of a wireless device (e.g., access point 110 and/or user terminal 120) may adjust the inductance by opening or closing switches within the switched inductor circuit 406 based on a mode of operation (e.g., low or high-band mode).

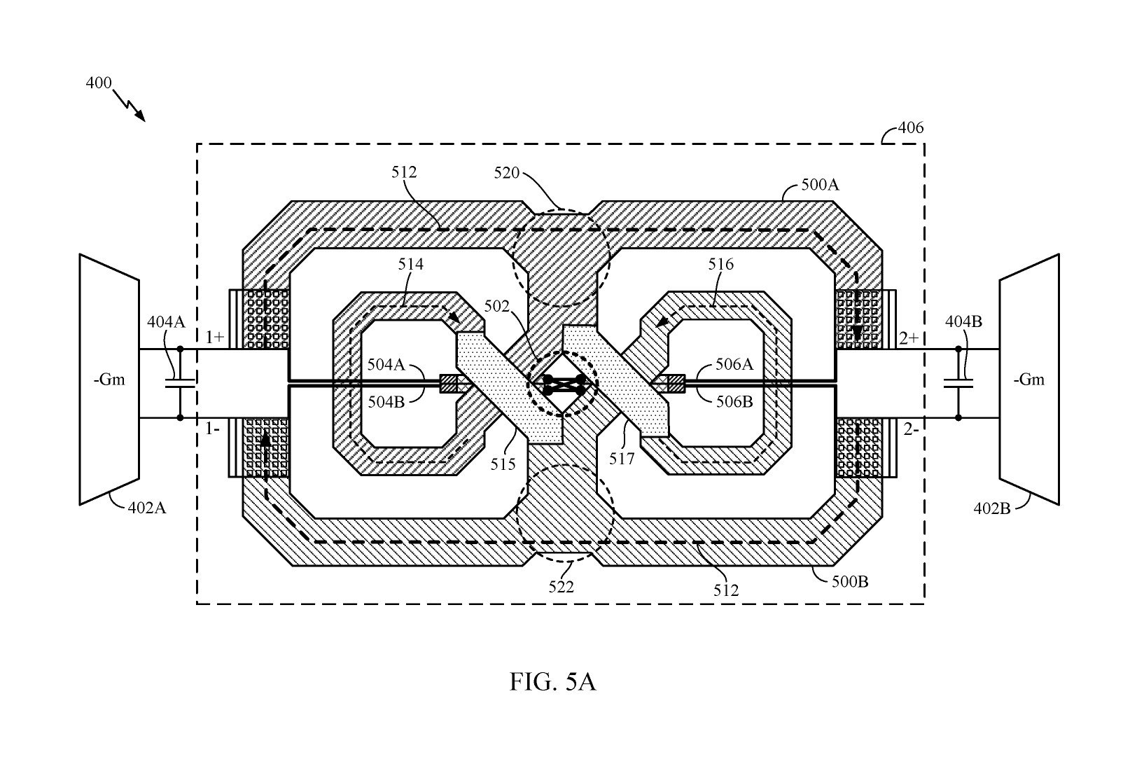

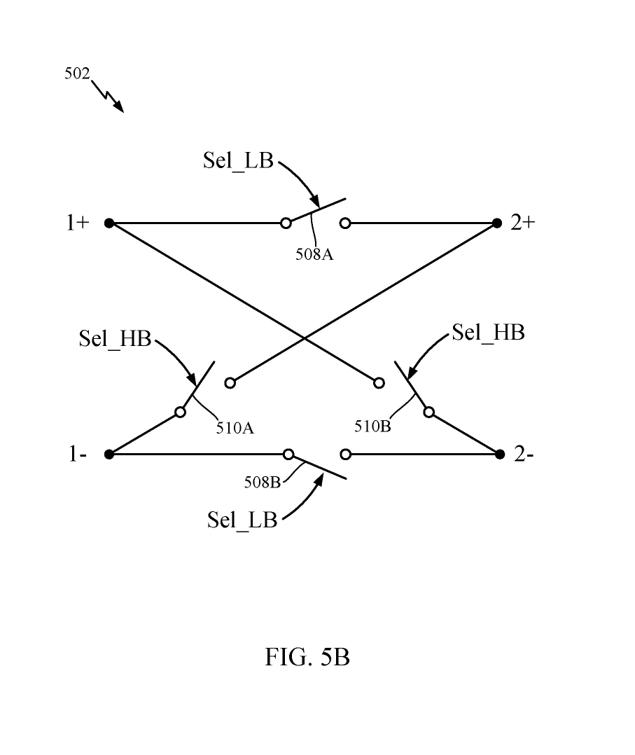

FIG. 5A illustrates an example layout of the switched inductor circuit 406, in accordance with certain aspects of the present disclosure. As illustrated, the switched inductor circuit layout includes two electrically conductive strips 500A and 500B (collectively “conductive strips 500”) forming an outer inductor loop 512 and two inner inductor loops 514 and 516. Two conductive strip sections 515 and 517 may be used to electrically connect conductive strip 500A with conductive strip 500B. The conductive strip sections 515 and 517 may exist on a different layer than the portions of the conductive strips 500 forming the inner inductor loops 514 and 516 in order to complete these loops. Conductive strip 500A may have a node 520, and conductive strip 500B may have a node 522. The portions of the conductive strips 500 and strip sections 515, 517 forming inner inductor loops 514 and 516 each connect node 520 with node 522.

Current flow from the negative transconductance circuits 402 may be adjusted using mode selection switches 502, as will be described in more detail with respect to FIG. 5B. The mode selection switches 502 are connected with the positive and negative voltage terminals 1+ and 1− of the resonant circuit via conductive strips 504A and 504B (collectively “conductive strips 504”) and are connected with the positive and negative voltage terminals 2+ and 2− via conductive strips 506A and 506B (collectively “conductive strips 506”). The conductive strips 504, 506 may be disposed on a different layer than the conductive strips 500 and may be connected with the conductive strips through the use of conductive vias. The conductive strips 504, 506 may be disposed on the same or a different layer than the conductive strip sections 515, 517.

FIG. 5B illustrates an example configuration of the mode selection switches 502 of FIG. 5A, in accordance with certain aspects of the present disclosure. Each of the mode selection switches 502 may be implemented with any of various suitable switching mechanisms, such as individual transistors (e.g., NMOS or PMOS transistors) or an arrangement of multiple transistors (e.g., T switches).

During a low-band mode of operation, switches 508A and 508B (collectively “switches 508”) may be closed via a low-band mode selection signal (labeled “Sel_LB”) (e.g., output by controller 230 or 280), while switches 510A and 510B (collectively “switches 510”), controlled via a high-band mode selection signal (labeled “Sel_HB”) (e.g., output by controller 230 or 280) may be open. In this configuration, the positive and negative voltage terminals 1+ and 1− of the resonant circuit are connected with the positive and negative voltage terminals 2+ and 2−, respectively.

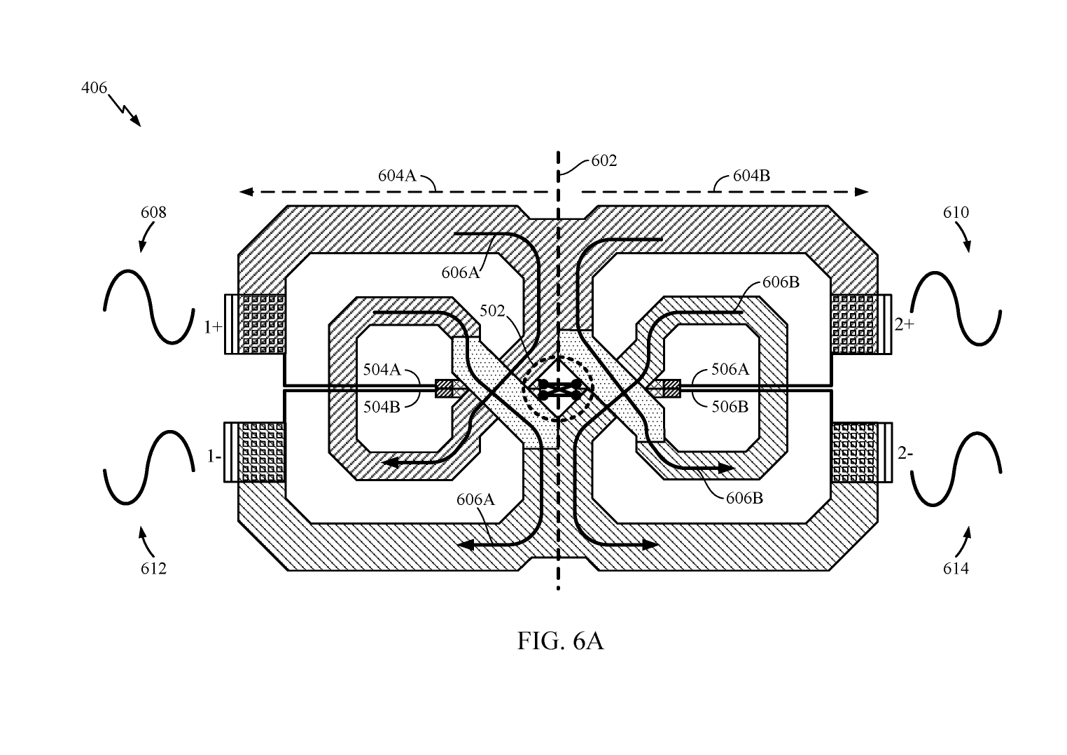

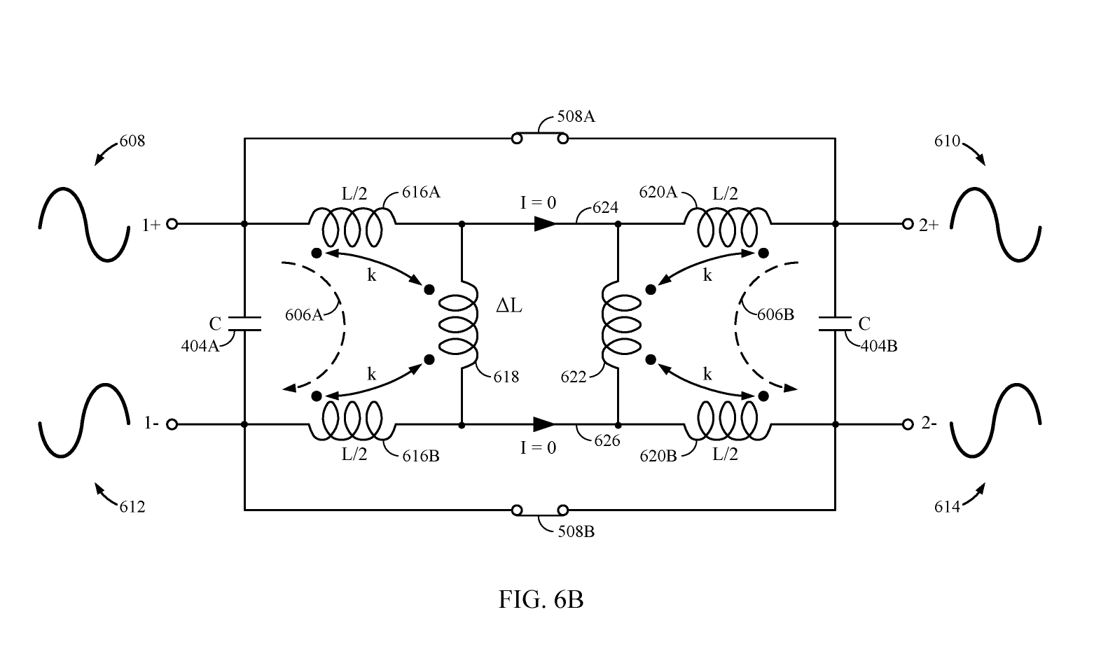

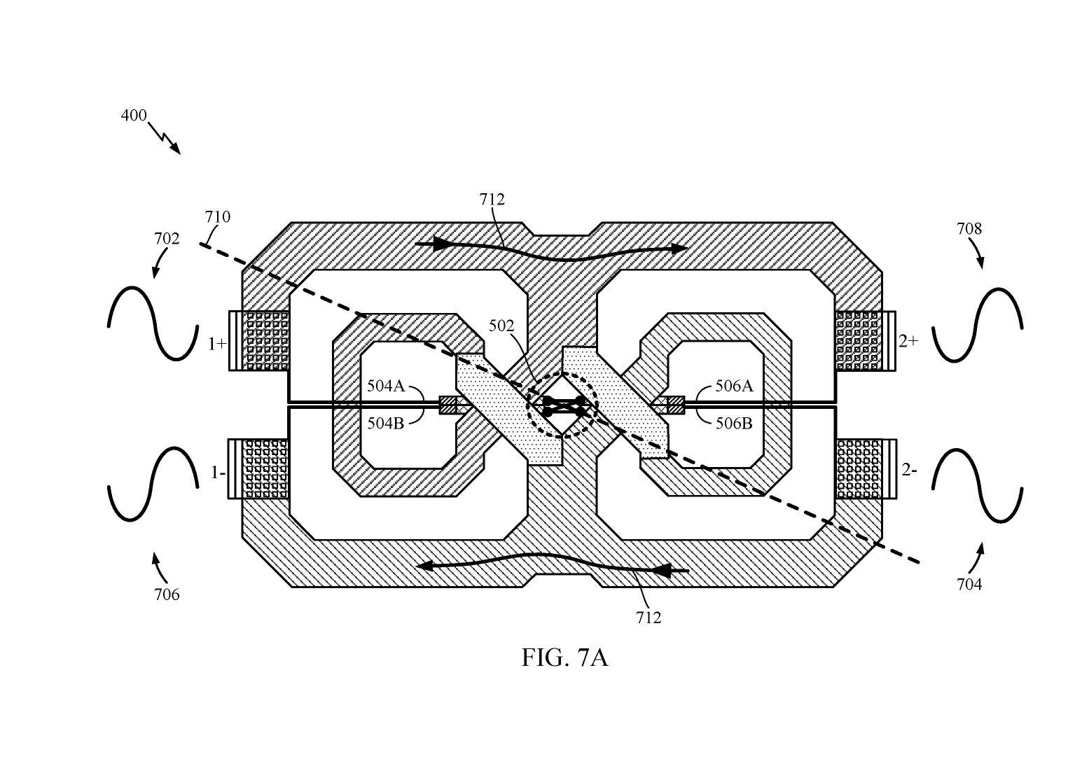

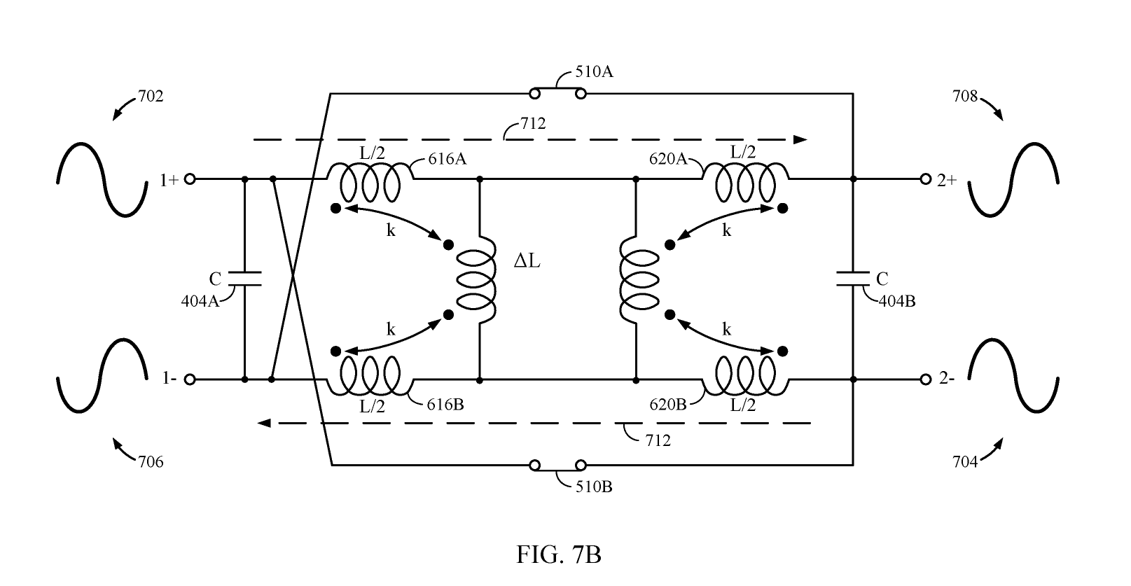

During a high-band mode of operation, switches 510 may be closed via the Sel_HB signal, connecting the positive and negative voltage terminals 1+ and 1− of the resonant circuit to the negative and positive voltage terminals 2− and 2+, respectively. By controlling the mode selection switches 502, the inductance of the switched inductor circuit 406 and the flow of current within the circuit are adjusted, which in turn alters the band (e.g., high/low-band) of the VCO 400, as described in more detail with respect to FIGS. 6A-7B. In certain aspects, each of the switches 508 and 510 may comprise an NMOS transistor. In this case, the Sel_LB signal may be logic high (low) to close (open) the switches 508, and the Sel_HB signal may be logic high (low) to close (open) the switches 510.

FIG. 6A illustrates example current flow through the layout of the switched inductor circuit 406 during a low-band mode of operation, in accordance with certain aspects of the present disclosure. As illustrated, the mode selection switches 502 are configured to connect conductive strip 504A with conductive strip 506A and connect conductive strip 504B with conductive strip 506B. Therefore, as illustrated in the equivalent circuit diagram of FIG. 6B, switches 508A and 508B are closed, connecting the positive and negative voltage terminals 1+ and 1− with the positive and negative voltage terminals 2+ and 2−, respectively. As a result, a signal 608 at the positive voltage terminal 1+ may be in phase with a signal 610 at the positive voltage terminal 2+ as shown. Likewise, a signal 612 at the negative voltage terminal 1− may be in phase with a signal 614 at the negative voltage terminal 2−.

Returning to FIG. 6A, a line of symmetry 602 exists between a first portion 604A and a second portion 604B of the switched inductor circuit layout (i.e., the first and second portions 604A, 604B are symmetrical around the imaginary line of symmetry 602). Thus, the line of symmetry 602 is also associated with the polarities of signals 608, 610, 612, and 614 because the polarity of signal 608 is the same as the polarity of signal 610, and the polarity of signal 612 is the same as the polarity of signal 614. Thus, current flow 606A from the negative transconductance circuit 402A flows in the first portion 604A of the outer inductor loop 512 and through the inner inductor loop 514. Similarly, current flow 606B from the negative transconductance circuit 402B flows in the second portion 604B of the outer inductor loop 512 and through the inner inductor loop 516.

As illustrated in FIG. 6B, the current flow 606A flows through inductors 616A and 616B (collectively “inductors 616,” each represented as having inductance L/2), corresponding to the current flow in the first portion 604A of the outer inductor loop 512, and through an inductor 618 (represented as having inductance ΔL) corresponding to the current flow in the inner inductor loop 514. The current flow 606B flows through inductors 620A and 620B (collectively “inductors 620,” each represented as having inductance L/2), corresponding to the current flow in the second portion 604B of the outer inductor loop 512, and through an inductor 622 (represented as having inductance ΔL), corresponding to the current flow in the inner inductor loop 516. There may be no current (or at most negligible current) flowing (I=0) in lines 624, 626 between the inductors 618, 622. As a result, there may be no significant Q degradation in the resonant circuit.

With the mode selection switches 502 configured for the low-band mode of operation, the low-band operating frequency (f_{LB}) may be calculated in accordance with the following equation:

$${f}_{LB} = \frac{1}{2 π \sqrt{( L + 2 M + Δ L ) C}}$$

where L is the combined inductance of inductors 616 (or inductors 620), M is the mutual inductance between inductors 616 and inductor 618 (or inductors 620 and inductor 622) (e.g., where the coupling factor is represented by variable k in FIG. 6B), ΔL is the inductance of inductor 618 (or inductor 622), and C is the capacitance of variable capacitive element 404A (or 404B). The mutual inductance M may be positive for the example layout of the switched inductor circuit 406 as illustrated in FIG. 5A. In this manner, the switched inductor circuit 406 may provide at least two degrees of freedom in designing the layout: M and ΔL. Having these degrees of freedom eases the design trade-offs for phase noise, power consumption, and tuning range for the VCO 400.

FIG. 7A illustrates example current flow through the layout of the switched inductor circuit 406 during a high-band mode of operation, in accordance with certain aspects of the present disclosure. As illustrated, the mode selection switches 502 are configured to connect conductive strip 504A with conductive strip 506B and to connect conductive strip 504B with conductive strip 506A. Therefore, as illustrated in the equivalent circuit diagram of FIG. 7B, switches 510A and 510B are closed, connecting the positive voltage terminal 1+ with the negative voltage terminal 2− and connecting the negative voltage terminal 1− with the positive voltage terminal 2+. Therefore, a signal 702 at the positive voltage terminal 1+ may be in phase with a signal 704 at the negative voltage terminal 2−, but 180° out of phase with a signal 708 at the positive voltage terminal 2+. Likewise, a signal 706 at the negative voltage terminal 1− may be in phase with the signal 708 at the positive voltage terminal 2+, but 180° out of phase with the signal 704 at the negative voltage terminal 2−.

Returning to FIG. 7A, a line of symmetry 710 associated with the polarities of signals 702, 704, 706, and 708 exists across the switched inductor circuit layout. That is, the polarity of signal 702 is the same as the polarity of signal 704, and the polarity of signal 706 is the same as the polarity of signal 708. Current flow 712 from the negative transconductance circuit 402A flows in the outer inductor loop 512, but not in the inner inductor loops 514, 516. As illustrated in FIG. 7B, the current flow 712 flows through inductors 616 and inductors 620, representing the outer inductor loop 512.

With the mode selection switches 502 configured for the high-band mode of operation, the high-band operating frequency (f_{HB}) may be calculated in accordance with the following equation:

$${f}_{HB} = \frac{1}{2 π \sqrt{L ( 1 - {k}^{2} ) C}}$$

where L is the combined inductance of inductors 616 (or inductors 620), k is the coupling factor between inductor 616A (or 616B) and inductor 618 (or equivalently, between inductor 620A (or 620B) and inductor 622), and C is the capacitance of variable capacitive element 404A (or 404B). Because the inductance in the high band does not include the mutual inductance M or the inductance ΔL as described, the total inductance of the resonant circuit in the high-band mode is lower than in the low-band mode. Thus, the high-band operating frequency is greater than the low-band operating frequency.

In certain aspects, all mode selection switches 502 (e.g., switches 508 and 510) may be opened in a wide-band mode of operation, for example. That is, by opening switches 508 and 510, both the low-band and high-band operating frequencies may be concurrently available.

The impedance of the traces (conductive strips and strip sections) and the mode selection switches 502 may most likely be taken into consideration when designing the layout of the switched inductor circuit 406 in an effort to prevent an unwanted mode of oscillation. For this purpose, the startup gain of the VCO 400 for the undesired mode of oscillation should be less than 1. In other words,

|Gm*(Rp∥Zon)|<1

where Gm is the total negative conductance of the cross-coupled core in the VCO, Rp is the tank resistance (i.e., the resistance of the resonant circuit) at the oscillation frequency, and Zon is the on-impedance of the switch. As a rule of thumb,

|Zon|<<Rp.

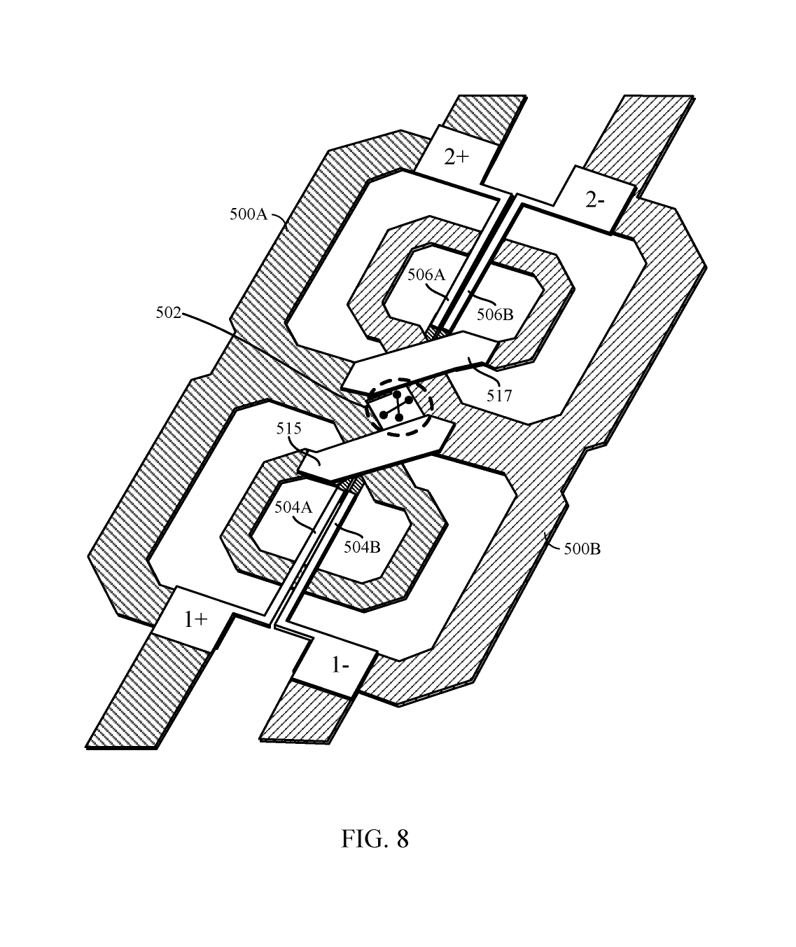

FIG. 8 is a three-dimensional (3D) illustration of an example layout of the switched inductor circuit 406, in accordance with certain aspects of the present disclosure. As illustrated, the terminals 1+ and 1− of the resonant circuit are connected with the mode selection switches 502 via conductive strips 504A and 504B, respectively, and terminals 2+ and 2− of the resonant circuit are connected with the mode selection switches 502 via conductive strips 506A and 506B, respectively. Thus, depending on the configuration of the mode selection switches 502, current flow in the switched inductor circuit 406 can be controlled, thereby adjusting the operating band of the VCO 400. As illustrated in FIG. 8, the conductive strips 504, 506 and the conductive strip sections 515, 517 are routed on the same layer, which is different from the layer used to route the conductive strips 500. Any of the conductive strips or strip sections described herein may be routed using any suitable layout technology, such as microstrip, stripline, and the like.

According to certain aspects, a mode selection bit for controlling the mode selection switches 502 can be considered as an additional bit (e.g., a most significant bit (MSB)) for coarse tuning of the VCO 400 without introducing any Q degradation of capacitive elements in coarse tuning capacitive banks. This may enable simpler switching from one mode to another mode and may facilitate the frequency plan, band assignment, and deployment of different division ratios compared to using multiple standalone VCOs.

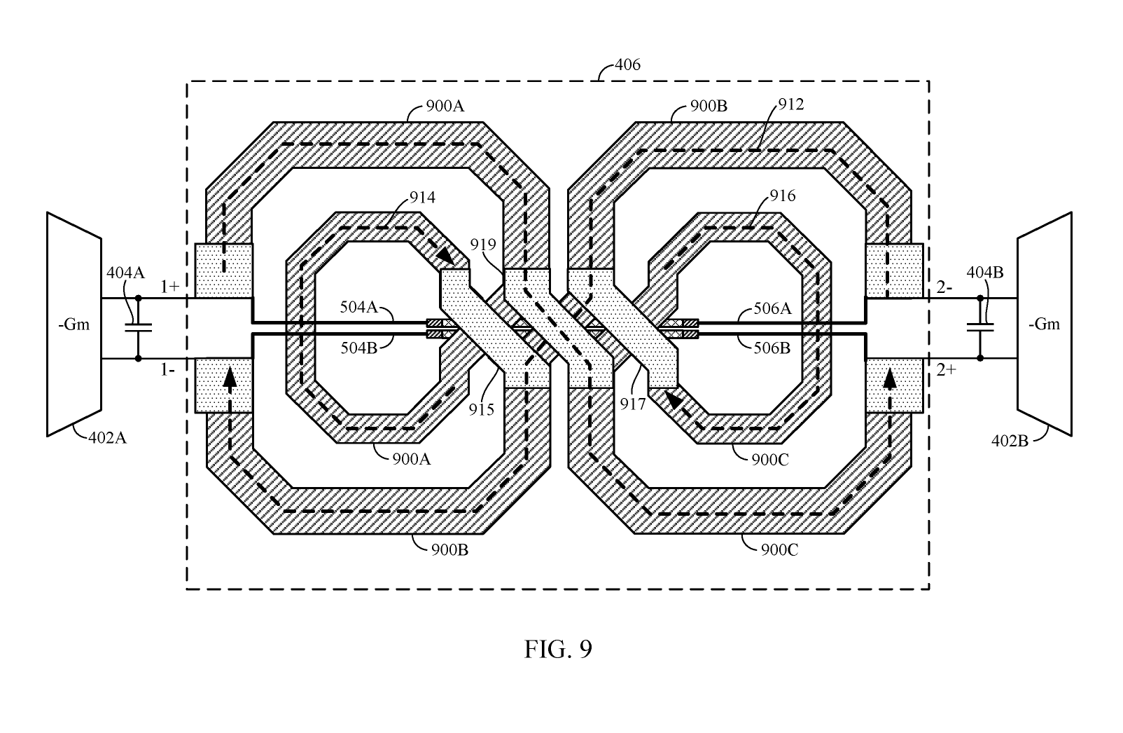

FIG. 9 illustrates another example layout of the switched inductor circuit 406, in accordance with certain aspects of the present disclosure. As illustrated, the switched inductor circuit layout includes electrically conductive strips 900A, 900B, and 900C (collectively “conductive strips 900”) forming an outer inductor loop 912 (shaped as a figure eight) and two inner inductor loops 914 and 916. A conductive strip section 915 may be used to electrically connect conductive strip 900A with conductive strip 900B. Another conductive strip section 917 may be used to electrically connect conductive strip 900B with conductive strip 900C. Yet another conductive strip section 919 may be used to electrically connect conductive strip 900A with conductive strip 900C. The conductive strip sections 915, 917, and 919 may exist on a different layer than the portions of the conductive strips 900 forming the inner inductor loops 914 and 916 in order to complete these loops.

Current flow from the negative transconductance circuits 402 may be adjusted using mode selection switches (not shown in FIG. 9) coupled to conductive strips 504 and 506, in a similar manner as presented above with respect to FIG. 5B. The conductive strips 504, 506 may be disposed on a different layer than the conductive strips 900 and may be connected with the conductive strips through the use of conductive vias, for example. The conductive strips 504, 506 may be disposed on the same or a different layer than the conductive strip sections 915, 917, and 919.

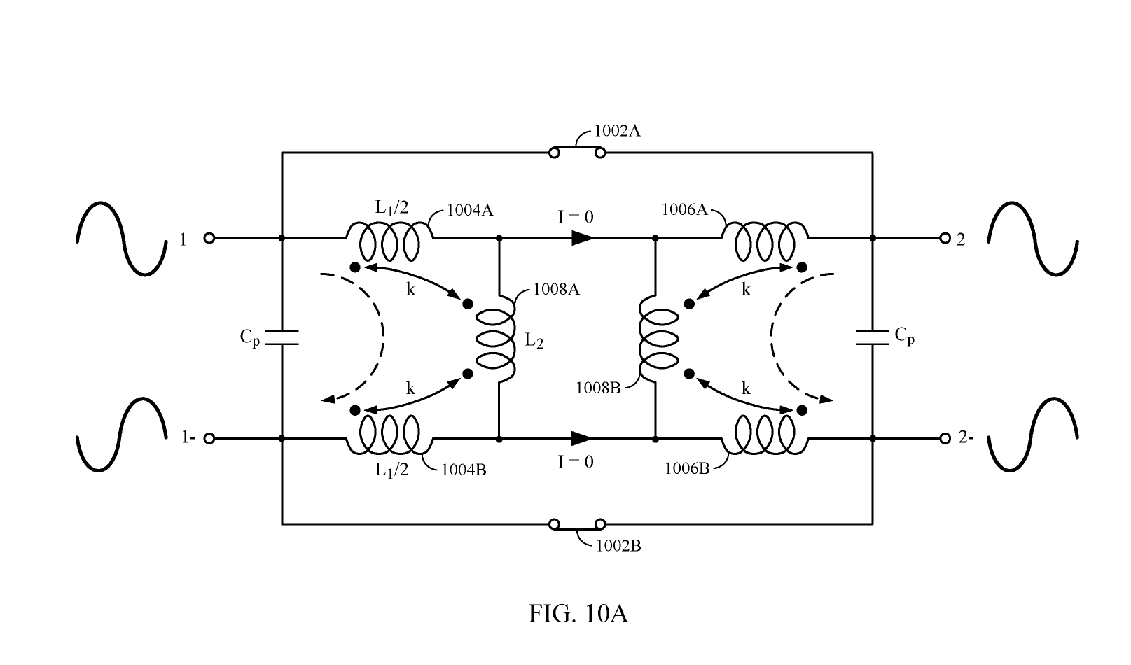

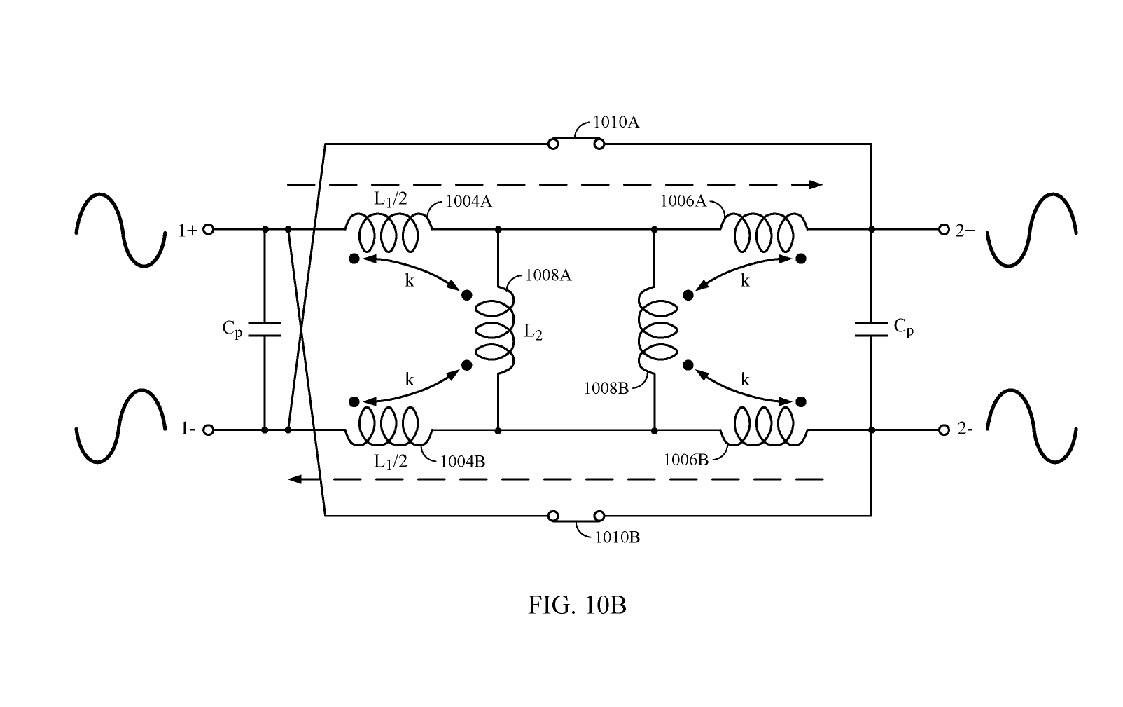

FIG. 10A is an equivalent circuit diagram for the switched inductor circuit of FIG. 9, illustrating an example configuration of the mode selection switches during a low-band mode of operation, in accordance with certain aspects of the present disclosure. As illustrated, during the low-band mode of operation, switches 1002A and 1002B may be closed, electrically connecting the positive and negative terminals 1+ and 1− with the positive and negative voltage terminals 2+ and 2−, respectively. In this configuration, no current may flow between the transconductors 402. Rather, current may flow between the positive and negative terminals of each of the transconductors 402 and in respective inner inductor loops 914 and 916. With the mode selection switches configured for the low-band mode of operation, the low-band operating frequency (f_{LB}) may be calculated in accordance with the following equation:

$${f}_{LB} = \frac{1}{2 π \sqrt{( {L}_{1} + {L}_{2} + 2 M ) C}}$$

where L₁ is the combined inductance of inductors 1004A and 1004B (or inductors 1006A and 1006B), L₂ is the inductance of inductor 1008A (or 1008B), M is the mutual inductance between inductor 1004A (or 1004B) and 1008A (or, equivalently, between inductor 1006A (or 1006B) and 1008B), and C is the capacitance of variable capacitive element 404A (or 404B).

FIG. 10B is an equivalent circuit diagram for the switched inductor circuit of FIG. 9, illustrating an example configuration of the mode selection switches during a high-band mode of operation, in accordance with certain aspects of the present disclosure. As illustrated, during the high-band mode of operation, switches 1010A and 1010B may be closed, electrically connecting the positive and negative terminals 1+ and 1− with the negative and positive voltage terminals 2− and 2+, respectively. In this configuration, no current may flow in the inner loops 914 and 916. Rather, current may flow between the transconductors 402 and in the outer inductor loop 912. With the mode selection switches configured for the high-band mode of operation, the high-band operating frequency (f_{HB}) may be calculated in accordance with the following equation:

$${f}_{HB} = \frac{1}{2 π \sqrt{L ( 1 - {k}^{2} ) C}}$$

where L₁, and C are defined above, and k is the coupling factor between inductor 1004A (or 1004B) and inductor 1008A (or equivalently, between inductor 1006A (or 1006B) and inductor 1008B).

The example layout of the switched inductor circuit 406 of FIG. 9 may provide a larger inductance L₁ during the high-band mode of operation, as compared to the example layout of the switched inductor circuit 406 of FIG. 5. A larger inductance L₁ may result in lower power consumption in this high-band mode.

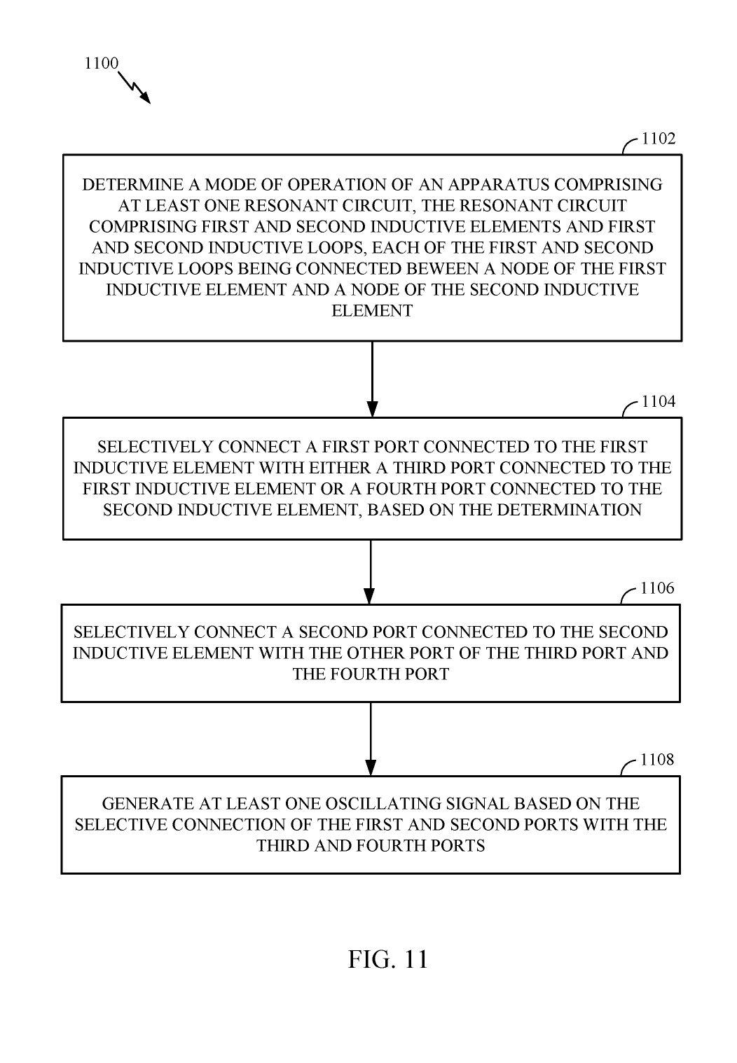

FIG. 11 illustrates example operations 1100 for generating at least one oscillating signal, in accordance with certain aspects of the present disclosure. The operations 1100 may be performed, for example, by a controller (e.g., the controller 230 or 280 of FIG. 2) in an apparatus (e.g., an access point 110 or user terminal 120).

The operations 1100 may begin, at block 1102, with the controller determining a mode of operation of the apparatus. The apparatus may include at least one resonant circuit. The resonant circuit may include a first inductive element (e.g., a portion of conductive strip 500A) and a second inductive element (a portion of conductive strip 500B). The resonant circuit may also include a first inductive loop (e.g., another portion of conductive strip 500A and conductive strip section 515 forming inner inductor loop 514) and a second inductive loop (e.g., another portion of conductive strip 500B and conductive strip section 517 forming inner inductor loop 516). Each of the first and second inductive loops may be connected between a node of the first inductive element (e.g., node 520) and a node of the second inductive element (e.g., node 522).

At block 1104, the controller may selectively connect a first port (e.g., terminal 1+) connected to the first inductive element with a third port (e.g., terminal 2+) connected to the first inductive element or a fourth port (e.g., terminal 2−) connected to the second inductive element, based on the determination at block 1102. At block 1106, the controller may selectively connect a second port (e.g., terminal 1−) connected to the second inductive element with the other of the third and fourth ports. The apparatus may generate at least one oscillating signal (e.g., using the resonant circuit) at block 1108 based on the selective connection of the first and second ports with the third and fourth ports.

In certain aspects, selectively connecting the first port and selectively connecting the second port involves closing a pair of switches (e.g., switches 508 or 510).

In certain aspects, the determining at block 1102 entails determining that the mode of operation comprises a relatively lower band mode of operation. In this case, the selectively connecting the first port at block 1104 may include connecting the first port with the third port and the selectively connecting the second port at block 1106 may involve connecting the second port with the fourth port.

In certain aspects, selectively connecting the first port with the third port at block 1104 and selectively connecting the second port with the fourth port at block 1106 involve: (A) directing current from a first negative transconductance circuit (e.g., circuit 402A) to flow in a portion of the first inductive element (e.g., first portion 604A of the conductive strip 500A) coupled between the first port and the third port, a portion (e.g., first portion 604A of the conductive strip 500B) of the second inductive element of the resonant circuit coupled between the second port and the fourth port, and the first inductive loop of the resonant circuit coupled between the first and second inductive elements and/or (B) directing current from a second negative transconductance circuit (e.g., circuit 402B) to flow in another portion of the first inductive element (e.g., second portion 604B of the conductive strip 500A), another portion of the second inductive element (e.g., second portion 604B of the conductive strip 500B), and the second inductive loop of the resonant circuit coupled between the first and second inductive elements.

In certain aspects, the determining at block 1102 involves determining that the mode of operation comprises a relatively higher band mode of operation. In this case, the selectively connecting the first port at block 1104 may include connecting the first port with the fourth port, and the selectively connecting the second port at block 1106 may involve connecting the second port with the third port.

In certain aspects, selectively connecting the first port with the fourth port at block 1104 and selectively connecting the second port with the third port at block 1106 entail directing current from a first negative transconductance circuit to flow in the first inductive element of the resonant circuit coupled between the first port and the third port and directing current from a second negative transconductance circuit to flow in the second inductive element of the resonant circuit coupled between the second port and the fourth port. In this case, the selectively connecting at blocks 1104 and 1106 may further include directing no current from the first negative transconductance circuit to the first inductive loop of the resonant circuit and directing no current from the second negative transconductance circuit to the second inductive loop of the resonant circuit, the first and second inductive loops coupled between the first and second inductive elements.

According to certain aspects, the at least one oscillating signal comprises a differential oscillating signal pair output from the third port and the fourth port. For certain aspects, the at least one oscillating signal comprises a differential oscillating signal pair output from the first port and the second port.

Certain aspects of the present disclosure provide a switched inductor VCO that can cover a wide frequency range (e.g., more than one octave). This single VCO offers simplicity of design, implementation, and floor plan compared to other designs using multiple VCOs to cover a similar frequency range. For example, the switched inductor VCO utilizes a smaller area than two separate VCOs. In certain aspects, the switched inductor VCO may incorporate only a single VCO buffer, only a single set of degeneration inductors, and/or only a single tuning voltage (Vtune), power supply, and ground routing. Furthermore, there is no inductor Q degradation with the mode-selection scheme of the switched inductor VCO.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for transmitting may comprise a transmitter (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for receiving may comprise a receiver (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for processing, means for closing, means for opening, means for directing, means for selectively connecting, means for determining, and/or means for controlling may comprise a processing system, which may include one or more processors, such as the RX data processor 270, the TX data processor 288, and/or the controller 280 of the user terminal 120 illustrated in FIG. 2. In certain aspects, means for selectively connecting and/or means for directing may include a switch such as the switches 508 and/or 510. Means for generating may comprise a VCO, such as the VCO 400 of FIG. 4.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A voltage-controlled oscillator (VCO), comprising:
a resonant circuit configured to generate at least one oscillating signal and having a first port, a second port, a third port, and a fourth port, the resonant circuit comprising:
a first inductive element connected between the first port and the third port and having a first node;
a second inductive element connected between the second port and the fourth port and having a second node;
a first inductive loop connected between the first node and the second node; and
a second inductive loop connected between the first node and the second node; and
a plurality of switches configured to selectively connect each of the first port and the second port with respective ones of the third port and the fourth port.

2. The VCO of claim 1, wherein the plurality of switches comprises:
a first pair of switches configured to selectively connect the first port with the third port and the second port with the fourth port; and
a second pair of switches configured to selectively connect the first port with the fourth port and the second port with the third port, wherein in a first mode of operation, the first pair of switches is closed and the second pair of switches is open.

3. The VCO of claim 2, wherein the first mode of operation comprises a relatively lower band mode of operation for the VCO.

4. The VCO of claim 2, further comprising:
a first negative transconductance circuit coupled to the first port and the second port of the resonant circuit; and
a second negative transconductance circuit coupled to the third port and the fourth port of the resonant circuit.

5. The VCO of claim 4, wherein the first and second negative transconductance circuits each comprise cross-coupled n-channel metal oxide semiconductor (NMOS) transistors.

6. The VCO of claim 4, wherein in the first mode of operation:
current from the first negative transconductance circuit is configured to flow in a portion of the first inductive element, a portion of the second inductive element, and the first inductive loop; and
current from the second negative transconductance circuit is configured to flow in another portion of the first inductive element, another portion of the second inductive element, and the second inductive loop.

7. The VCO of claim 4, wherein in a second mode of operation, the first pair of switches is open and the second pair of switches is closed.

8. The VCO of claim 7, wherein the second mode of operation comprises a relatively higher band mode of operation for the VCO.

9. The VCO of claim 7, wherein in the second mode of operation:
current from the first negative transconductance circuit is configured to flow in the first inductive element; and
current from the second negative transconductance circuit is configured to flow in the second inductive element.

10. The VCO of claim 9, wherein in the second mode of operation:
the current from the first negative transconductance circuit does not flow in the first inductive loop; and
the current from the second negative transconductance circuit does not flow in the second inductive loop.

11. The VCO of claim 7, wherein in the second mode of operation:
a signal at the first port is configured to be 180 degrees out of phase with a signal at the third port; and
a signal at the second port is configured to be 180 degrees out of phase with a signal at the fourth port.

12. The VCO of claim 7, wherein in a third mode of operation, the first pair of switches and the second pair of switches are open.

13. The VCO of claim 12, wherein the third mode of operation comprises a wide-band mode of operation for the VCO.

14. The VCO of claim 2, wherein in the first mode of operation:
a signal at the first port is configured to be in phase with a signal at the third port; and
a signal at the third port is configured to be in phase with a signal at the fourth port.

15. The VCO of claim 1, wherein the resonant circuit further comprises a first capacitor connected between the first and second ports and a second capacitor connected between the third and fourth ports.

16. The VCO of claim 1, wherein the at least one oscillating signal comprises a differential oscillating signal pair output from the third port and the fourth port.

17. The VCO of claim 1, wherein the first inductive loop and the second inductive loop are surrounded by the first inductive element and the second inductive element.

18. The VCO of claim 1, wherein a layout of the first inductive element and the second inductive element has a line of symmetry and wherein the first node and the second node are on the line of symmetry.

19. The VCO of claim 18, wherein a layout of the first inductive loop and the second inductive loop is symmetrical around the line of symmetry.

20. The VCO of claim 1, wherein each switch in the first and second pairs of switches comprises an n-channel metal oxide semiconductor (NMOS) transistor.

21. The VCO of claim 1, wherein the first inductive element crosses over the second inductive element.

22. A method for generating at least one oscillating signal, comprising:
determining a mode of operation of an apparatus comprising at least one resonant circuit, the resonant circuit comprising:
first and second inductive elements; and
first and second inductive loops, each of the first and second inductive loops being connected between a node of the first inductive element and a node of the second inductive element;
selectively connecting a first port connected to the first inductive element with either a third port connected to the first inductive element or a fourth port connected to the second inductive element, based on the determination;
selectively connecting a second port connected to the second inductive element with the other port of the third port and the fourth port; and
generating the at least one oscillating signal based on the selective connection of the first and second ports with the third and fourth ports.

23. The method of claim 22, wherein selectively connecting the first port and selectively connecting the second port comprise closing a pair of switches.

24. The method of claim 22, wherein:
the determining comprises determining that the mode of operation comprises a relatively lower band mode of operation;
selectively connecting the first port comprises connecting the first port with the third port; and
selectively connecting the second port comprises connecting the second port with the fourth port.

25. The method of claim 22, wherein selectively connecting the first port with the third port and selectively connecting the second port with the fourth port comprise:
directing current from a first negative transconductance circuit to flow in a portion of the first inductive element of the resonant circuit coupled between the first port and the third port, a portion of the second inductive element of the resonant circuit coupled between the second port and the fourth port, and the first inductive loop of the resonant circuit coupled between the first and second inductive elements; and
directing current from a second negative transconductance circuit to flow in another portion of the first inductive element, another portion of the second inductive element, and the second inductive loop of the resonant circuit coupled between the first and second inductive elements.

26. The method of claim 22, wherein:
the determining comprises determining that the mode of operation comprises a relatively higher band mode of operation;
selectively connecting the first port comprises connecting the first port with the fourth port; and
selectively connecting the second port comprises connecting the second port with the third port.

27. The method of claim 22, wherein selectively connecting the first port with the fourth port and selectively connecting the second port with the third port comprise:
directing current from a first negative transconductance circuit to flow in the first inductive element of the resonant circuit coupled between the first port and the third port; and
directing current from a second negative transconductance circuit to flow in the second inductive element of the resonant circuit coupled between the second port and the fourth port.

28. The method of claim 27, further comprising:
directing no current from the first negative transconductance circuit to the first inductive loop of the resonant circuit; and
directing no current from the second negative transconductance circuit to the second inductive loop of the resonant circuit, the first and second inductive loops coupled between the first and second inductive elements.

29. An apparatus for generating at least one oscillating signal, comprising:
means for determining a mode of operation of the apparatus having a resonant circuit, the resonant circuit comprising:
first and second inductive elements; and
first and second inductive loops, each of the first and second inductive loops being connected between a node of the first inductive element and a node of the second inductive element;
means for selectively connecting a first port connected to the first inductive element with either a third port connected to the first inductive element or a fourth port connected to the second inductive element, based on the determination;
means for selectively connecting a second port connected to the second inductive element with the other port of the third port and the fourth port; and
means for generating the at least one oscillating signal based on the selective connection of the first and second ports with the third and fourth ports.
